(19) United States
(12) Patent Application Publication
(10) Pub. No.: US 2013/0026434 A1
(43) Pub. Date: Jan. 31, 2013

(54) MEMRISTOR WITH CONTROLLED ELECTRODE GRAIN SIZE

(71) Applicants: Jianhua Yang, Palo Alto, CA (US); John Pual Strachan, Millbrae, CA (US); Matthew D. Pickett, San Diego, CA (US); R. Stanley Williams, Portola Valley, CA (US)

(72) Inventors: Jianhua Yang, Palo Alto, CA (US); John Pual Strachan, Millbrae, CA (US); Matthew D. Pickett, San Diego, CA (US); R. Stanley Williams, Portola Valley, CA (US)

(21) Appl. No.: 13/383,634

(22) PCT Filed: Jan. 29, 2010
(86) PCT No.: PCT/US10/22644

§ 371 Date: Jan. 12, 2012

(51) Int. Cl. H01L 45/00

(52) U.S. Cl. 257/1; 438/382; 257/E45.002

(57) ABSTRACT

A memristor with a controlled electrode grain size includes an adhesion layer, a first electrode having a first surface contacting the adhesion layer and a second surface opposite the first surface, in which the first electrode is formed of an alloy of a base material and at least one second material, and in which the alloy has a relatively smaller grain size than a grain size of the base material. The memristor also includes a switching layer positioned adjacent to the second surface of the first electrode and a second electrode positioned adjacent to the switching layer.

### CROSS-REFERENCE TO RELATED APPLICATION

The present application has the same Assignee and shares some common subject matter with U.S. Patent Application Publication No. 20080090337, filed on Oct. 3, 2006, by R. Stanley Williams, the disclosure of which is hereby incorporated by reference in its entirety.

### GOVERNMENT LICENSE RIGHTS

This invention was made in the course of research partially supported by grants from the U.S. Government. The U.S. Government has certain rights in the invention.

### BACKGROUND

Solid state memristive devices rely on the drift of mobile charge dopants upon the application of an electrical field, as discussed in the Patent Publication 20080090337. These types of devices have been found to have promising properties in the fields of both digital and analog non-volatile electronic logic and memory. To illustrate the increase potential of analog non-volatile electronic logic, synaptic computing has emerged as a potential technology that is enabled by the relatively small size, low cost, and low power consumption provided by solid state memristive devices.

A cross-sectional side view of a conventional solid state memristive device 10 is depicted in FIG. 1. As shown therein, the memristive device 10 includes a titanium adhesion layer 12, a first platinum electrode 14, a second platinum electrode 16, and a titanium dioxide layer 20. The first platinum electrode 14 is depicted as including grain boundaries 18. During the fabrication process, titanium atoms from the titanium layer 12 are configured to diffuse through the first platinum electrode 14, and more particularly through the grain boundaries 18 in the platinum material. The areas in which the grain boundaries 18 interface with the titanium dioxide layer 20 are construed as switching seed locations 30 because it is at those locations that at least partial conductance channels 32 have a greater probability of forming.

The first platinum electrode 14 is depicted as including a relatively small number of grain boundaries 18 because the first platinum electrode 14 is formed of a pure metal, which has a relatively large grain size. There are thus a relatively small number of switching seed locations 30 at the interface between the grain boundaries 18 and the titanium dioxide layer 20. The number of switching seed locations 30 is reduced further as memristive devices 10 having smaller areas of overlap between the first platinum electrode 14 and the second platinum electrode 16 are designed. For instance, there may be no grain boundaries in memristive devices having an overlap area smaller than around 50×50 nm. As such, the probability that a functional conductance channel is formed through the titanium dioxide layer 20 reduces greatly as the sizes of the memristive devices 10 decrease, which has been a barrier to the design and implementation of ever-smaller memristive devices 10.

### BRIEF DESCRIPTION OF THE DRAWINGS

Embodiments are illustrated by way of example and not limited in the following figure(s), in which like numerals indicate like elements, in which:

FIG. 1 depicts a cross-sectional side view of a conventional solid state memristive device;

FIG. 2 illustrates a perspective view of an electrically actuated apparatus or a memristor, according to an embodiment of the invention;

FIG. 3 illustrates a crossbar array employing a plurality of the electrically actuated apparatuses or memristors depicted in FIG. 2, according to an embodiment of the invention; and

FIG. 4 illustrates a flow diagram of a method for fabricating an electrically actuated apparatus or memristor, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is an electrically actuated apparatus, which is equivalently recited herein as a memristor, formed of a pair of spaced apart electrodes with a switching layer positioned between the electrodes. It should thus be understood that the terms “electrically actuated device” and “memristor” are used interchangeably throughout the present disclosure. In any regard, an adhesion layer is provided at a side of a first electrode opposite a second electrode. The first electrode is formed of an alloy composed of a base material and at least one second material. The base material and the at least one second material may comprise metals that are substantially nonreactive with the material forming the adhesion layer. As discussed herein below, the alloy contains grain sizes that are significantly smaller than the grain sizes of pure metals typically employed in memristor devices. The smaller grain sizes results in a relatively larger number of grain boundaries to be formed throughout the first electrode, and thus, a larger number of switching seed locations from which conductance channels may be formed in the switching layer. This increased number of switching seed locations improves the probability that functional conductance channels will form and thus improves the performance of the electrically actuated apparatus disclosed herein as compared with conventional memristive devices.

Micron-scale dimensions refer to dimensions that range from 1 micrometer to a few micrometers in size.

Sub-micron scale dimensions refer to dimensions that range from 0.1 nanometers to 5 nanometers (0.005 micrometers).

Micron-scale and submicron-scale wires refer to rod or ribbon-shaped conductors or semiconductors with widths or diameters having the dimensions of 0.04 to 10 micrometers, heights that can range from a few nanometers to a micrometer, and lengths of several micrometers and longer.

For the purposes of this application, nanometer scale dimensions refer to dimensions ranging from 1 to 5 nanometers. In addition, nanostructures have nano-scale dimensions and comprise wires, rod or ribbon-shaped conductors or semiconductors with widths or diameters having nanoscale dimensions.

An electrically actuated apparatus, such as a memristor, is a two-terminal dynamical electrical device in which the magnetic flux between the terminals is a function of the amount of electric charge that has passed through the device.

A crossbar is an array of electrically actuated apparatuses, here memristors, that can connect each wire (or electrode) in one set of parallel wires (electrodes) to every member of a second set of parallel wires (or electrodes) that intersects the first set (usually the two sets of wires are perpendicular to each other, but this is not a necessary condition).

As used herein, the functional dimension of the device is measured in nanometers (typically less than 50 nm), but the lateral dimensions may be nanometers, sub-microns or microns.

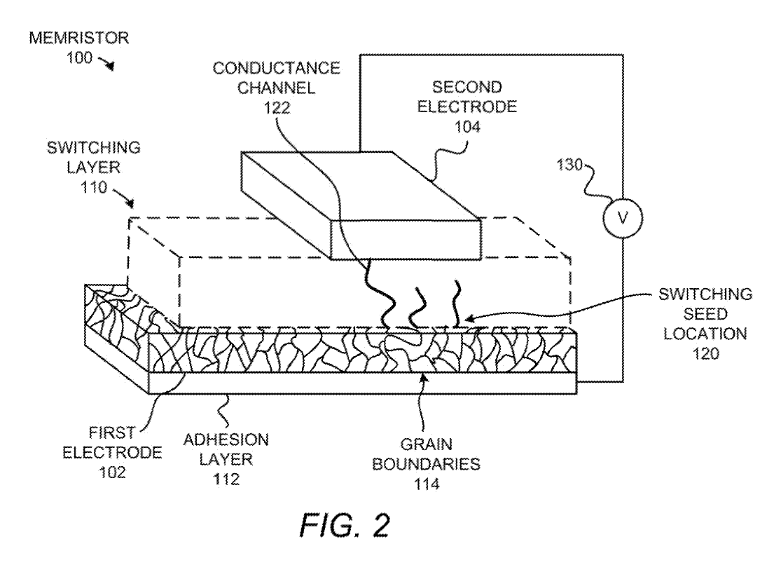

With reference first to FIG. 2, there is shown a perspective view of an electrically actuated apparatus or memristor 100, according to an embodiment. It should be understood that the electrically actuated apparatus 100 depicted in FIG. 2 may include additional components and that some of the components described herein may be removed and/or modified without departing from a scope of the electrically actuated apparatus 100. It should also be understood that the components depicted in FIG. 2 are not drawn to scale and thus, the components may have different relative sizes with respect to each other than as shown therein.

Generally speaking, the electrically actuated apparatus 100 depicted in FIG. 2 may be built at the micro- or nano-scale and used as a component in a wide variety of electronic circuits. For instance, the electrically actuated apparatus 100 may be used as the basis for memories, switches, and logic circuits and functions. When used as a basis for memories, the electrically actuated apparatus 100 may be used to store a bit of information, 1 or 0. When used as a switch, the electrically actuated apparatus 100 may either be a closed or open switch in a cross-point memory. When used as a logic circuit, the electrically actuated apparatus 100 may be employed as bits in a logic circuit that resembles a Field Programmable Gate Array, or as the basis for a wired-logic Programmable Logic Array. The electrically actuated apparatus 100 disclosed herein is also configured to find uses in a wide variety of other applications.

As depicted in FIG. 2, the electrically actuated apparatus 100 includes a first electrode 102, a switching layer 110, a second electrode 104, and an adhesion layer 112 positioned beneath the first electrode 102. In addition, the first electrode 102 is in a crossed arrangement with respect to the second electrode 104. The second electrode 104 may be positioned on the switching layer 110 such that a portion of the second electrode 104 is substantially in line with and overlaps at least a portion of the first electrode 102. One or both of the first electrode 102 and the second electrode 104 may be formed of metal or semiconductor materials. By way of particular example, both of the first electrode 102 and the second electrode 104 are formed of, for instance, platinum, gold, titanium, silver, or the like. In addition, the switching layer 110 may include a metal oxide, for instance, titanium dioxide (TiO₂) or other oxide species, such as nickel oxide or zinc oxide, etc. In other examples, the switching layer 110 may be formed of nitrides and/or sulfides.

In particular, the first electrode 102 is formed of an alloy of a base material and at least one second material. Generally speaking, the base material and the at least one second material comprise materials that are nonreactive with a material that forms the adhesion layer 112. In addition, the base material and the at least one second material comprise materials, that when combined into an alloy, have grain sizes that are relatively smaller than the grain size of the base material, which comprises, for instance, a pure metal. Moreover, the base material and the at least one second material comprise materials, that when combined into an alloy, forms an electrically conductive alloy. As such, for instance, the base material and the at least one second material may comprise various types of metals. More particularly, the base material and the at least one second material may comprise various types of noble metals. The reduction of the grain size of the alloy electrode will be favored in instances where the base material and the second material do not form a continuous solid solution and have a relatively large difference in their element sizes. For example, the base material and the at least one second material is selected from platinum, palladium, gold, tantalum, cobalt, osmium, iridium, rhodium, molybdenum, yttrium, erbium, gadolinium, terbium, samarium, tungsten, ruthenium, copper, hafnium, etc. By way of particular example, the base material comprises platinum and the at least one second material comprises at least one of tungsten or molybdenum. Examples of manners in which the base material and the second material may be selected to form the alloy for the electrode may be found in the article by Yang, et al., entitled “The Formation of Amorphous Alloy Oxides as Barriers Used in Magnetic Tunnel Junctions”, Journal of Applied Physics, Oct. 13, 2005, the disclosure of which is hereby incorporated by reference in its entirety.

As further shown in FIG. 2, the first electrode 102 includes a plurality of grain boundaries 114. In comparison with a conventional electrode formed of a pure metal, the alloy of the first electrode 102 includes a significantly larger number of grain boundaries 114 due to the relatively smaller grain sizes of the alloy as compared with the pure metal. As such, the electrically actuated apparatus 100 may comprise a relatively smaller size as compared with conventional electrically actuated apparatuses, while still having a relatively high probability of functional conductance channel formation. In one embodiment, the electrically actuated apparatus 100 comprises a relatively small size, for instance, the junction in the switching layer 110 between the first electrode 102 and the second electrode 104 has an area that is smaller than about 50 nm×50 nm. In another embodiment, the junction has an area that is smaller than about 30 nm×30 nm. In a further embodiment, the junction has an area that is smaller than about 20 nm×20 nm.

In any regard, the relatively large number of grain boundaries 114 results in a relatively large number of switching seed locations 120 at the interface of the switching layer 110 and the grain boundaries 114 in the first electrode 102. As such, there is a relatively high probability that one or more conductance channels 122 will form in the switching layer 110 under an applied electric field from the switching seed locations 120.

During the device operation, an electrical field is generated through the switching layer 110 by a voltage source 130, which causes a localized field-driven atomic modification to occur in the switching layer 110. This process includes applying a sufficiently high (threshold) voltage across the first electrode 102 and the second electrode 104 for a sufficient length of time to cause the conductive channel(s) 122 in the switching layer 110 to form. The threshold voltage and the length of time required for this process may depend upon the type of material used for the switching layer 110, the first electrode 102 and the second electrode 104.

More particularly, during the fabrication process, and more particularly, during an annealing process, atoms from the adhesion layer 112 are diffused through the grain boundaries 114 of the first electrode 102 and operate as seeds for the conductance channel 122 to be formed. In other words, for instance, the atoms of the adhesion layer react with the switching layer 110 material and form local clusters of oxygen deficient regions in which an electrical field concentrating effect occurs. The conductance channels 122 are generally formed from the regions in which the electrical field concentrating effect occurs.

Generally speaking, the adhesion layer 112 is formed of a material that reacts with materials in the switching layer 110. Examples of suitable materials for the adhesion layer 112 include titanium, chromium, zirconium, hafnium, aluminum, silicon, vanadium, scandium, and the like. By way of particular example in which the switching layer 110 is formed of titanium dioxide, the adhesion layer 112 may be formed of titanium, which takes oxygen atoms from the titanium dioxide in the switching layer 110.

Although particular reference has been made throughout the present disclosure that the first electrode 102 positioned below the switching layer 110 is formed of an alloy of a base material and at least one second material, it should be understood that the second electrode 104 positioned above the switching layer 110 may instead be formed the alloy of materials without departing from a scope of the electrically actuated apparatus 100. In this example, the adhesion layer 112 may be positioned above the second electrode 104 in FIG. 2. In addition, or alternatively, both the first electrode 102 and the second electrode 104 may be formed of the alloy.

In addition, although the switching layer 110 has been depicted as having a similar size as the first and second electrodes 102, 104, it should be understand that the switching layer 110 may extend substantially outside of the junction area and may extend to junctions between other first and second electrodes (not shown).

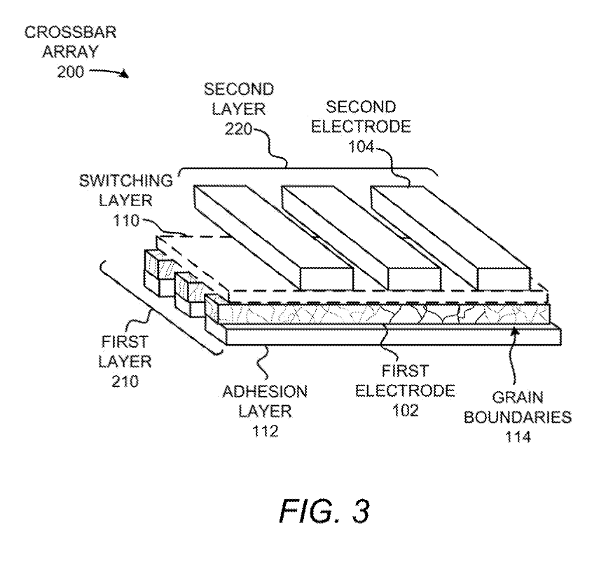

With reference now to FIG. 3, there is shown a crossbar array 200 employing a plurality of the electrically actuated apparatuses 100 shown in FIG. 2, according to an embodiment. It should be understood that the crossbar array 200 depicted in FIG. 3 may include additional components and that some of the components described herein may be removed and/or modified without departing from a scope of the crossbar array 200.

As shown in FIG. 3, a plurality of adhesion layers 112 is overlain by a first layer 210 of approximately parallel first electrodes 102. The first layer 210 is overlain by a second layer 220 of approximately parallel second electrodes 104. The second layer 220 is roughly perpendicular, in orientation, to the first electrodes 102 of the first layer 210, although the orientation angle between the layers may vary. The two layers 210, 220 form a lattice, or crossbar, with each second electrode 104 of the second layer 220 overlying a plurality of the first electrodes 102 of the first layer 210 and coming into close contact with the plurality of first electrodes 102 of the first layer 210 at respective junction areas, which represent the closest contact between two of the first and second electrodes 102 and 104. The crossbar array 200 depicted in FIG. 3 may be fabricated from micron-, submicron or nanoscale-electrodes 102, 104, depending on the application.

As also shown in FIG. 3, the first electrode 102 includes a plurality of the grain boundaries 114 and the switching layer 110 extends between the first layer 210 and the second layer 220. In this regard, and as discussed above, a relatively large number of switching seed locations may be provided at the interfaces between the first electrodes 102 and the switching layer 110 to thus increase the probability of functional conductance channels forming in the switching layer 110 at the junctions between the first electrodes 102 and the second electrodes 104.

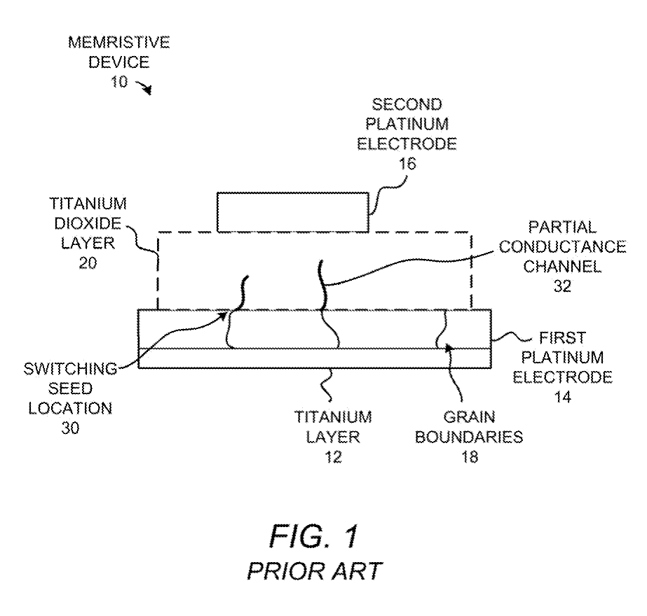

Although the first electrodes 102 and second electrodes 104 adhesion layers 112 depicted in FIGS. 1 and 2 are shown with rectangular cross-sections, the first electrodes 102, the second electrodes 104, and/or adhesion layers 112 may have circular, elliptical, or more complex cross-sections. The first electrodes 102, the second electrodes 104, and/or adhesion layers 112 may also have many different widths or diameters and aspect ratios or eccentricities. The term “nanowire crossbar” may refer to crossbars having one or more layers of sub-microscale electrodes, microscale electrodes or electrodes with larger dimensions, in addition to nanowires.

According to another example, the adhesion layers 112 may be positioned on top of the second electrodes 104 and the second electrodes 104 may be formed of the alloy of materials. In addition, or alternatively, both the first electrodes 102 and the second electrodes 104 are formed of the alloy of materials.

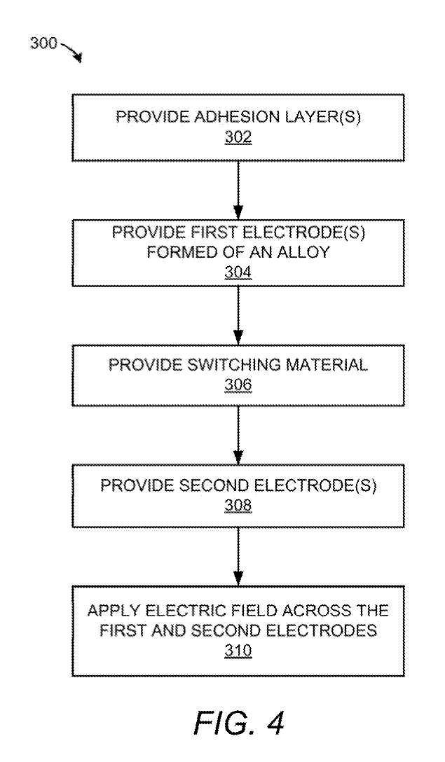

Turning now to FIG. 4, there is shown a flow diagram of a method 300 for fabricating an electrically actuated apparatus or memristor 100, according to an embodiment. It should be understood that the method 300 depicted in FIG. 4 may include additional steps and that some of the steps described herein may be removed and/or modified without departing from a scope of the method 300. For instance, the second electrode 104 may be placed on the bottom of the memristor 100 and steps 308-302 disclosed below may be reversed.

At step 302, one or more adhesion layers 112 are provided. The adhesion layer(s) 112 may be provided through a formation process, such as, E-beam evaporation, chemical vapor deposition, sputtering, etching, lithography, etc.

At step 304, one or more first electrodes 102 formed of an alloy of a base material and at least one second material are provided on the adhesion layer(s) 112. According to an example, the base material and the at least one second material are co-deposited, such as, through sputter deposition, pulse laser deposition, atomic layer deposition, chemical vapor deposition, electroplating, etc. to form the first electrode(s) 102. According to another example, the base material and the at least one second material are interspersed into the alloy prior to deposition of the alloy to form the first electrode(s) 102. In addition, the first electrode(s) 102 may undergo an etching or lithographic processes to obtain desired configurations.

At step 306, a switching layer 110 is provided upon the first electrode(s) 102. According to an example, the switching layer 110 is grown on the first electrode 102. The switching layer 110 may be grown through use of, for instance, sputtering, metal-catalyzed growth from vapor, liquid, or solid-phase precursors, growth from a chemical solution, or rapid deposition of material vaporized from a solid source. In addition, at step 306, a top surface of the switching layer 110 may be planarized, for instance, by chemical-mechanical polishing to create a relative smooth surface.

At step 308, one or more second electrodes 104 are formed on the switching layer 110. The second electrode(s) 104 may be provided such that portions of the second electrode(s) 104 are substantially in line with and overlap sections of the first electrode(s) 102.

At step 310, an electric field is applied across the first and the second electrodes to cause one or more conduction channels 122 to be formed from one or more switching seed locations 120 at the interface between the switching layer 110 and grain boundaries in the first electrode(s) 102.

It should be understood that the electrically actuated apparatus 100 depicted in the figures discussed above may be modified in various respects without departing from a scope of those disclosed electrically actuated apparatus 100. By way of example, the switching layer 110 may be composed of a dual layer structure as described in greater detail in the 20080090337 U.S. Patent Application Publication. As disclosed therein, the dual layer structure of the switching layer enhances the switching properties and operation of devices using electrically actuated switches constructed therewith. That application for patent also describes a wide combination of materials that can be used to facilitate the switching process using the dual layer structure.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

1. A memristor with a controlled electrode grain size, said memristor comprising:
an adhesion layer;
a first electrode having a first surface contacting the adhesion layer and a second surface opposite the first surface, wherein the first electrode is formed of an alloy of a base material and at least one second material, wherein the alloy has a relatively smaller grain size than a grain size of they base material;
a switching layer positioned adjacent to the second surface of the first electrode; and
a second electrode positioned adjacent to the switching layer.

2. The memristor of claim 1, wherein at least a portion of the second electrode overlaps at least a portion of the first electrode and wherein the switching layer is positioned within an area of the overlapped region.

3. The memristor of claim 1, wherein the area of the overlapped region is smaller than about 50 nm×50 nm.

4. The memristor of claim 1, wherein the area of the overlapped region is smaller than about 30 nm×30 nm.

5. The memristor of claim 1, wherein the at least one second material comprises a material that is relatively nonreactive with a material forming the adhesion layer.

6. The memristor of claim 1, wherein the base material and the at least one second material are selected from the group consisting of platinum, palladium, gold, tantalum, cobalt, osmium, iridium, rhodium, molybdenum, yttrium, erbium, gadolinium, terbium, samarium, tungsten, ruthenium, copper, and hafnium.

7. The memristor of claim 1, wherein the adhesion layer is formed of a material that is to diffuse through one or more grain boundaries formed by grains of the first electrode and to react with the switching layer to form one or more conductance channels through the switching layer.

8. The memristor of claim 1, wherein the adhesion layer is formed of a metallic material selected from the group consisting of titanium; chromium, zirconium, and hafnium, aluminum, silicon, vanadium, and scandium.

9. A method for fabricating the memristor, said method comprising:
providing an adhesion layer;
providing a first electrode having a first surface contacting the adhesion layer and a second surface opposite the first surface, wherein the first electrode is formed of an alloy of a base material and at least one second material, wherein the alloy has a relatively smaller grain size than a grain size of the base material;
providing a switching layer adjacent to the second surface of the first electrode; and
providing a second electrode adjacent to the switching layer such that at least a portion of the second electrode overlaps at least a portion of the first electrode.

10. The method of claim 9, wherein providing the first electrode further comprises co-depositing the base material and the at least one second material.

11. The method of claim 9, wherein providing the first electrode further comprises implementing at least one of a sputter deposition, chemical vapor deposition, electroplating, atomic layer deposition, and pulse laser deposition operation to form the first electrode with the base material and the at least one second material.

12. The method of claim 9, further comprising:
applying an electric field across the first and the second electrodes on the memristor to form one or more conductance channels in the switching layer.

13. A crossbar array comprising:
an adhesion layer;
a plurality of first electrodes, each of said plurality of first electrodes having a first surface contacting the adhesion layer and a second surface opposite the first surface, wherein each of the plurality of first electrodes is formed of an alloy of a base material and at least one second material, wherein the alloy has a relatively smaller grain size than a grain size of the base material;
a switching layer positioned adjacent to the second surfaces of the plurality of first electrodes; and
a plurality of second electrodes positioned adjacent to the switching layer.

14-15. (canceled)

16. The crossbar array according to claim 13, wherein at least portions of the plurality of second electrodes overlap at least portions of the plurality of first electrodes, and wherein the switching layer is positioned within an area of the overlapped portions.

17. The crossbar array according to claim 13, wherein the adhesion layer is formed of a material that is to diffuse through one or more grain boundaries formed by grains of the plurality of first electrodes and to react with the switching layer to form one or more conductance channels through the switching layer.
